(19) United States
(12) Patent Application Publication
(10) Pub. No.: US 2008/0266764 A1
(43) Pub. Date: Oct. 30, 2008

(54) CASING AND MOBILE COMMUNICATION APPARATUS

(75) Inventor: Yu-Chun YANG, Taipei (TW)

Correspondence Address: Muncy, Geissler, Olds & Lowe, PLLC, P.O. BOX 1364, FAIRFAX, VA, 22038-1364, US

(73) Assignee: ASUSTeK COMPUTER INC.

(21) Appl. No.: 12/111,743

(22) Filed: Apr. 29, 2008

(30) Foreign Application Priority Data
Apr. 30, 2007 (TW) 096115346

(51) Int. Cl. H05K 5/00

(52) U.S. Cl. 361/679

(57) ABSTRACT

A casing of a mobile communication device includes a casing body, a cover and a screwing assembly. The outside of the casing body has a battery holding recess and a screw hole. The cover can cover the battery holding recess. The screwing assembly is fixed to the cover. The screwing assembly is screwed in the screw hole to fix the cover to the casing body or partially screwed out of the screw hole to rotate and raise the cover from the casing body. A mobile communication device is also disclosed.

### CROSS REFERENCE TO RELATED APPLICATIONS

This Non-provisional application claims priority under 35 U.S.C. §119(a) on Patent Application No(s). 096115346 filed in Taiwan, Republic of China on Apr. 30, 2007, the entire contents of which are hereby incorporated by reference.

### BACKGROUND OF THE INVENTION

1. Field of Invention

The invention relates to a casing and a mobile communication device and, more particularly, to a casing with an improved battery cover and a mobile communication device using the same.

2. Related Art

Along with the progress of the science and technology, portable electronic products have a development tendency to be functional and miniature, for example mobile communication devices such as mobile phones, personal digital assistants and so on.

As shown in FIG. 1, a conventional mobile communication device 1 has a casing 11 and a battery 12. The casing 11 has a casing body 111 and a battery cover 112. The casing body 111 has a battery holding recess 1111, and the battery 12 is held in the battery holding recess 1111. The battery cover 112 is disposed at the battery holding recess 1111 to cover the battery 12. When a user wants to put in or take out the battery 12, he only needs to slide the battery cover 12 away, and then he can put in or take out the battery 12.

Since the battery cover 112 is operated in a sliding mode, to allow the user to slide the battery cover 112 conveniently, the battery cover 112 usually extends to the lower side 1112 of the casing body 111 to form a sliding stoke D further to facilitate the operation of the user.

The battery cover 112 has to include the portion extending to the lower side 1112 of the casing body 111, which wastes material. Electronic components are held in holding space S of the casing body 111. When the battery cover 112 is completely slid away, the electronic components are exposed. To avoid damaging the exposed electronic components, a protection layer 113 is provided above the electronic components to shield and protect the electronic components, and then cost increases, and the space utilized by the protection layer 113 is wasted.

### SUMMARY OF THE INVENTION

The objective of the invention is to provide a casing and a mobile communication device using the same to decrease material cost of its battery cover and to save interior space of the casing.

To achieve the above objective, the casing of a mobile communication device of the invention includes a casing body, a cover and a screwing assembly. The outside of the casing body has a battery holding recess and a screw hole. The cover covers the battery holding recess. The screwing assembly is fixed to the cover, and it is screwed on the screw hole to fix the cover to the casing body or partially screwed out of the screw hole to rotate and raise the cover from the casing body.

To achieve the above objective, a mobile communication device of the invention includes a casing and a battery. The casing includes a casing body, a cover and a screwing assembly. The outside of the casing body has a battery holding recess and a screw hole. The cover covers the battery holding recess. The screwing assembly is fixed to the cover, and it is screwed in the screw hole to fix the cover to the casing body or partially screwed out of the screw hole to rotate and raise the cover from the casing body. The battery is held in the battery holding recess. When the cover is rotated from the casing body, the battery is allowable to be separated from the battery holding recess.

From the above, in a casing and a mobile communication device of the invention, a cover is used to cover a battery holding recess of a casing body. When a user wants to put in or take out a battery, he only needs to screw the screwing assembly out of the screw hole of the casing body, and then he can put in or take out the battery. The screwing assembly is fixed to the cover. Therefore, when the screwing assembly is screwed out of the screw hole, the cover is driven by the screwing assembly to rise relatively to the casing body, and then it can be rotated to allow the user to take out the battery conveniently. Compared with the conventional technology, the invention utilizes a screwing mode instead of a sliding cover mode, and then no sliding stroke is needed. Therefore, the cover does not need to include a portion extending to the lower side of the casing body, which decreases material cost of the cover. The conventional protection layer for protecting electronic components is not needed, and then the interior space of the casing is saved.

### BRIEF DESCRIPTION OF THE DRAWINGS

The invention will become more fully understood from the detailed description and accompanying drawings, which are given for illustration only, and thus are not limitative of the present invention, and wherein:

FIG. 1 is a schematic diagram showing a conventional mobile communication device;

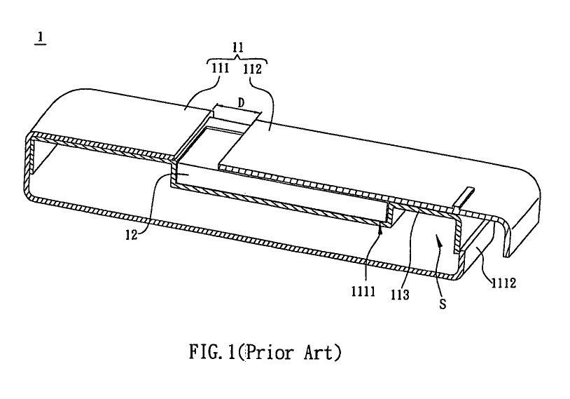

FIG. 2 is a schematic diagram showing a casing of a mobile communication device according to a preferred embodiment of the invention;

FIG. 3 is a schematic diagram showing a mobile communication device according to a preferred embodiment of the invention; and

FIG. 4 is a sectional view showing part of a mobile communication device according to a preferred embodiment of the invention.

### DETAILED DESCRIPTION OF THE INVENTION

The present invention will be apparent from the following detailed description, which proceeds with reference to the accompanying drawings, wherein the same references relate to the same elements.

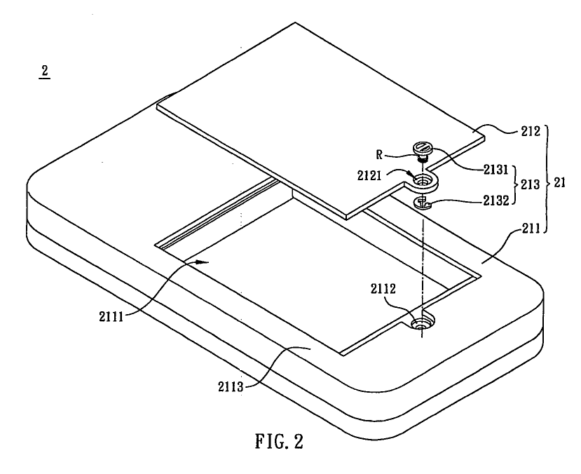

As shown in FIG. 2, a mobile communication device 2 of a preferred embodiment of the invention includes a casing 21. The casing 21 has a casing body 211, a cover 212 and a screwing assembly 213. The casing body 211 has a battery holding recess 2111 and a screw hole 2112. The battery holding recess 2111 and the screw hole 2112 are disposed at the outside 2113 of the casing 211, and the battery holding recess 2111 is provided adjacently to the screw hole 2112. The battery holding recess 2111 may be used to hold a battery. The mobile communication device 2 may be, for example, a mobile phone, a personal digital assistant or a media player, but it is not limited.

The cover 212 covers the battery holding recess 2111. The screwing assembly 213 is fixed to the cover 212, and it screwed to the screw hole 2112 to fix the cover 212 to the casing body 211 or be partially screwed out of the screw hole 2112 to rotate and raise the cover 212 from the casing body 211. In the embodiment, the screwing assembly 213 includes a manual knob 2131 and a fastener 2132.

In the embodiment, the screwing assembly 213 can be fixed to the cover 212 by passing through a hole 2121 of the cover 212. During assembly, the manual knob 2131 is provided through the hole 2121 first. The hole 2121 is located at the edge of the cover 212. Next, the fastener 2132 is fastened to a ringed concave portion R of the manual knob 2131 to fasten the cover 212 and the manual knob 2131. Herein, the fastener 2132 may be an E-shaped ring or a C-shaped ring. The screwing assembly 213 is fixed to the cover 212 through the hole 2121. Finally, the manual knob 2131 is rotated to lock the screwing assembly 213 to the screw hole 2112. When the manual knob 2131 is rotated in an opposite direction, the screwing assembly 213 is screwed out of the screw hole 2112.

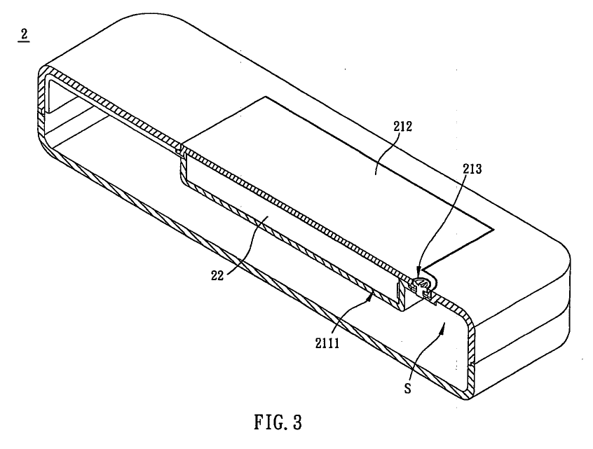

As shown in FIG. 3, the mobile communication device 2 further includes a battery 22 held in the battery holding recess 2111. The battery 22 can be connected to one side of the cover 212 or not. In the embodiment, the cover 212 is locked to the casing body 211, and it covers the battery holding recess 2111. For holding space S in the casing body 211, since the screwing mode is used to replace the sliding mode, a conventional protection layer is not needed to be provided at the holding space S to protect electronic components in the holding space S, and then the interior space of the casing body 211 is saved.

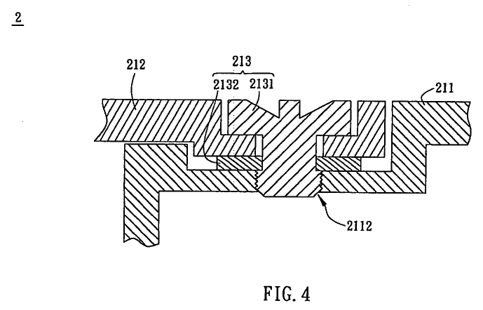

FIG. 4 is a sectional view showing part of the mobile communication device 2. As shown in FIG. 4, the screwing assembly 213 is fixed to the cover 212. Therefore, when the manual knob 2131 is screwed out of the screw hole 2112, the cover 212 is driven by the screwing assembly 213 to rise relatively to the casing body 211, and then it can be rotated to allow a user to take out the battery 22 conveniently.

To sum up, in a casing and a mobile communication device of the invention, a cover is used to cover a battery holding recess of a casing body and is locked to the casing body. When a user wants to put in or take out a battery, he only needs to screw the screwing assembly out of the screw hole of the casing body, and then he can put in or take out the battery. The screwing assembly is fixed to the cover. Therefore, when the screwing assembly is screwed out of the screw hole, the cover is driven by the screwing assembly to rise relatively to the casing body, and then it can be rotated to allow the user to take out the battery conveniently. Compared with the conventional technology, the invention utilizes a screwing mode instead of a sliding cover mode, and then no sliding stroke is needed. Therefore, the cover does not need to include a portion extending to the lower side of the casing body, which decreases material cost of the cover. A conventional protection layer for protecting electronic components is not needed, and then the interior space of the casing is saved.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A casing of a mobile communication device comprising:
a casing body, wherein the outside of the casing body has a battery holding recess and a screw hole;
a cover covering the battery holding recess; and
a screwing assembly fixed at the cover, wherein the screwing assembly is screwed in the screw hole to fix the cover to the casing body, or partially screwed out of the screw hole to rotate and raise the cover from the casing body.

2. The casing according to claim 1, wherein the screwing assembly comprises a manual knob, and the screwing assembly is screwed in or screwed out of the screw hole via the rotation of the manual knob.

3. The casing according to claim 1, wherein the cover has a hole, and the screwing assembly is fixed to the cover through the hole.

4. The casing according to claim 3, wherein the screwing assembly has a manual knob and a fastener, the manual knob is provided through the hole, and the fastener fastens the cover and the manual knob.

5. The casing according to claim 4, wherein the manual knob has a ringed concave portion, and the fastener is fastened at the concave portion.

6. The casing according to claim 4, wherein the fastener is an E-shaped ring or a C-shaped ring.

7. The casing according to claim 1, wherein when the cover is separated from the casing body, the cover can be rotated.

8. A mobile communication device comprising:
a casing comprising:
a casing body, wherein the outside of the casing body has a battery holding recess and a screw hole;
a cover covering the battery holding recess; and
a screwing assembly fixed at the cover, wherein the screwing assembly is screwed in the screw hole to fix the cover to the casing body, or it can be partially screwed out of the screw hole to separate the cover from the casing body; and
a battery held at the battery holding recess;
wherein when the cover is separated from the casing body, the casing body can be rotated to allow the battery to be separated from the battery holding recess.

9. The mobile communication device according to claim 8, wherein the screwing assembly comprises a manual knob, and the screwing assembly is screwed in or out of the screw hole via the rotation of the manual knob.

10. The mobile communication device according to claim 8, wherein the cover has a hole, and the screwing assembly is fixed to the cover through the hole.

11. The mobile communication device according to claim 10, wherein the screwing assembly has a manual knob and a fastener, the manual knob is provided through the hole, and the fastener fastens the cover and the manual knob.

12. The mobile communication device according to claim 11, wherein the manual knob has a ringed concave portion, and the fastener is fastened at the concave portion.

13. The mobile communication device according to claim 11, wherein the fastener is an E-shaped ring or a C-shaped ring.

14. The mobile communication device according to claim 8, wherein the battery is connected to one side of the cover.

15. The mobile communication device according to claim 8, wherein the mobile communication device is a mobile phone, a personal digital assistant or a media player.
